(19) United States
(12) Patent Application Publication
(10) Pub. No.: US 2026/0120732 A1
(43) Pub. Date: Apr. 30, 2026

(54) ENABLE SIGNAL GENERATION CIRCUIT AND SEMICONDUCTOR APPARATUS INCLUDING THE SAME

(71) Applicant: SK hynix Inc., Icheon-si Gyeonggi-do (KR)

(72) Inventor: Hyun Seung KIM, Icheon-si Gyeonggi-do (KR)

(73) Assignee: SK hynix Inc., Icheon-si Gyeonggi-do (KR)

(21) Appl. No.: 19/055,261

(22) Filed: Feb. 17, 2025

(30) Foreign Application Priority Data
Oct. 28, 2024 (KR) 10-2024-0148610

(51) Int. Cl. G11C 7/22; H03K 21/08; H03L 7/00

(52) U.S. Cl. CPC G11C 7/222; H03K 21/08; H03L 7/00

(57) ABSTRACT

An enable signal generation circuit includes a signal generation circuit, a counting circuit, and an activation interval adjustment circuit. The signal generation circuit synchronizes a command to a clock signal to activate an enable signal, and deactivates the enable signal in response to a deactivation control signal. The counting circuit counts the clock signal to generate a plurality of count result signals when the enable signal is activated. The activation interval adjustment circuit generates the deactivation control signal at a first timing based on transition timings of the plurality of count result signals when the command is input.

### CROSS-REFERENCES TO RELATED APPLICATION

The present application claims priority under 35 U.S.C. § 119(a) to Korean application number 10-2024-0148610 filed on Oct. 28, 2024, in the Korean Intellectual Property Office, which application is incorporated herein by reference in its entirety.

### BACKGROUND

### 1. Technical Field

Various embodiments generally relate to a semiconductor circuit, and, more particularly, to an enable signal generation circuit that generates an enable signal having a defined activation interval synchronously to a clock signal and a semiconductor apparatus including the same.

### 2. Related Art

A semiconductor apparatus, for example, a semiconductor memory apparatus, in response to an external command, generates an enable signal to set an interval for performing an operation corresponding to the command. The semiconductor apparatus includes a plurality of enable signal generation circuits for generating various enable signals corresponding to various commands, such as a write command and a read command.

FIG. 1 is a diagram illustrating an enable signal generation circuit 10 according to a prior art, and FIG. 2 is a diagram illustrating an operation of the enable signal generation circuit 10 of FIG. 1.

Referring to FIGS. 1 and 2, the enable signal generation circuit 10 according to the prior art includes a plurality of flip flops 11 to 14 and a plurality of logic gates 15 and 16.

The plurality of flip flops 11 to 14 generate a plurality of shift signals SFT1 to SFT4 by sequentially shifting a command CMD input from an external of a semiconductor apparatus according to a clock signal CLK.

The plurality of logic gates 15 and 16 performs an OR operation on the plurality of shift signals SFT1 to SFT4 and outputs an enable signal EN.

In FIG. 1, an example of generating the enable signal EN having an activation interval of 4 tCK, i.e., an activation interval corresponding to 4 cycles of the clock signal CK, is shown. As a target activation interval of the enable signal EN increases, the number of flip-flops for configuring each of the plurality of enable signal generation circuits increases.

Therefore, the prior art suffers from an increase in circuit area and an increase in asynchronous timing due to the logic circuits being asynchronous devices for performing the OR operation on the plurality of shift signals.

### SUMMARY

In an embodiment, an enable signal generation circuit may include a signal generation circuit, a counting circuit, and an activation interval adjustment circuit. The signal generation circuit may be configured to synchronize a command to a clock signal to activate an enable signal, and may be configured to deactivate the enable signal in response to a deactivation control signal. The counting circuit may be configured to count the clock signal to generate a plurality of count result signals when the enable signal is activated. The activation interval adjustment circuit may be configured to generate the deactivation control signal at a first timing among transition timings of the plurality of count result signals when the command is input.

In an embodiment, a semiconductor apparatus may include a memory core, a data input/output circuit, a plurality of enable signal generation circuits, and a memory control circuit. The memory core may include a plurality of memory cells. The data input/output circuit may be configured to be coupled to the memory core, and may be configured to exchange data with an external system or the memory core. The plurality of enable signal generation circuits may be configured to count a clock signal to generate a plurality of count result signals, may be configured to generate a deactivation control signal at a first timing determined according to a plurality of activation interval setting signals among transition timings of the plurality of count result signals, may be configured to synchronize a command to the clock signal to activate an enable signal, and may be configured to deactivate the enable signal according to the deactivation control signal. The memory control circuit may be configured to be coupled to the memory core and the data input/output circuit, and may be configured to provide the plurality of activation interval setting signals, the command provided from an external source, and the clock signal to the plurality of enable signal generation circuits.

In an embodiment, an enable signal generation circuit may include a signal generation circuit and an activation interval adjustment circuit. The signal generation circuit may be configured to synchronize a command to a clock signal to activate an enable signal, and may be configured to deactivate the enable signal in response to an activation of a deactivation control signal. The activation interval adjustment circuit may be configured to extend an activation interval of the enable signal by blocking an activation of the deactivation control signal when a first command of the command is input and a second command of the command is input before a first timing.

### BRIEF DESCRIPTION OF THE DRAWINGS

FIG. 1 is a diagram illustrating an enable signal generation circuit according to a prior art.

FIG. 2 is a diagram illustrating an operation of the enable signal generation circuit of FIG. 1.

FIG. 3 is a diagram illustrating an enable signal generation circuit according to an embodiment of the present disclosure.

FIG. 4 is a diagram illustrating a signal generation circuit of FIG. 3.

FIG. 5 is a diagram illustrating a counting circuit of FIG. 3.

FIG. 6 is a diagram illustrating an activation interval adjustment circuit of FIG. 3.

FIG. 7 is a timing diagram according to an example of an operation of an enable signal generation circuit according to an embodiment of the present disclosure.

FIG. 8 is a timing diagram according to another example of an operation of an enable signal generation circuit according to an embodiment of the present disclosure.

FIG. 9 is a timing diagram according to another example of an operation of an enable signal generation circuit according to an embodiment of the present disclosure.

FIG. 10 is a diagram illustrating a semiconductor apparatus according to an embodiment of the present disclosure.

### DETAILED DESCRIPTION

In various embodiments, flip-flops and asynchronous devices are not used, allowing an activation interval of an enable signal to be adjusted and extended by simply setting a test mode or a mode register. This approach can reduce circuit area and prevent asynchronous timing issues.

Hereinafter, embodiments of the present disclosure will be described in more detail with reference to the accompanying drawings.

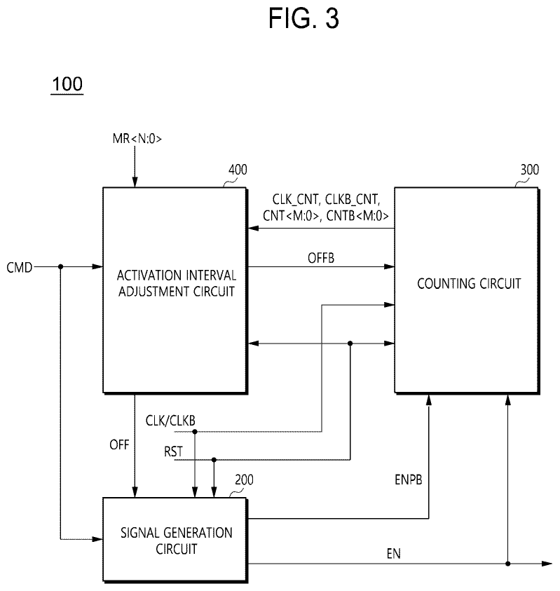

FIG. 3 is a diagram illustrating an enable signal generation circuit 100 according to an embodiment of the present disclosure.

Referring to FIG. 3, the enable signal generation circuit 100 may include a signal generation circuit 200, a counting circuit 300, and an activation interval adjustment circuit 400.

The signal generation circuit 200 may receive a command CMD, a deactivation control signal OFF, clock signals CLK/CLKB, and a reset signal RST as inputs, and may output an activation control signal ENPB and an enable signal EN. The command CMD may be a signal with a defined high level interval to indicate a write operation request or a read operation request. The clock signals CLK/CLKB may be a differential signal, and the CLK and the CLKB may have opposite logic levels.

The signal generation circuit 200 may activate the enable signal EN in response to the command CMD. The signal generation circuit 200 may synchronize the command CMD to the clock signals CLK/CLKB to activate the enable signal EN, and may deactivate the enable signal EN in response to the deactivation control signal OFF. The signal generation circuit 200 may extend an activation interval of the enable signal EN if another command CMD is input prior to activation of the deactivation control signal OFF. The signal generation circuit 200 may initialize the enable signal EN in response to the reset signal RST.

The counting circuit 300 may receive the activation control signal ENPB, the enable signal EN, the clock signals CLK/CLKB, an inverted deactivation control signal OFFB, and the reset signal RST, and may output count clock signals CLK_CNT/CLKB_CNT, a count reset signal CNT_RST, and a plurality of count result signals CNT<M:0> and CNTB<M:0> . ‘M’ may be defined as a non-negative integer. In the count clock signals CLK_CNT/CLKB_CNT, the CLK_CNT and the CLKB_CNT may have opposite logic levels. The count result signals CNT<M:0> and the count result signals CNTB<M:0> may have opposite logic levels.

The counting circuit 300 may generate the plurality of count result signals CNT<M:0> and CNTB<M:0> by counting the clock signals CLK/CLKB when the enable signal EN is activated. The counting circuit 300 may generate the count clock signals CLK_CNT/CLKB_CNT according to the enable signal EN and the clock signals CLK/CLKB and may generate the plurality of count result signals CNT<M:0> and CNTB<M:0> according to the count clock signals CLK_CNT/CLKB_CNT. The counting circuit 300 may generate the count reset signal CNT_RST according to the activation control signal ENPB and the inverted deactivation control signal OFFB. The counting circuit 300 may initialize the plurality of count result signals CNT<M:0> and CNTB<M:0> according to the count reset signal CNT_RST.

The activation interval adjustment circuit 400 may receive the command CMD, a plurality of activation interval setting signals MR<N:0>, the count clock signals CLK_CNT/CLKB_CNT, the reset signal RST, and the plurality of count result signals CNT<M:0> and CNTB<M:0> and may output the deactivation control signal OFF and the inverted deactivation control signal OFFB. ‘N’ may be defined as a non-negative integer.

The activation interval adjustment circuit 400 may generate the deactivation control signal OFF according to the plurality of count result signals CNT<M:0> and CNTB<M:0>. When the command CMD is input, the activation interval adjustment circuit 400 may activate the deactivation control signal OFF at a timing that corresponds to the plurality of activation interval setting signals MR<N:0> and transition timings of the plurality of count result signals CNT<M:0> and CNTB<M:0>. The activation interval adjustment circuit 400 may initialize the deactivation control signal OFF in response to the reset signal RST.

The command CMD may be input multiple times in a staggered manner. Therefore, in the following description, when the command CMD is input multiple times with a time difference, the command CMD at an earlier timing is referred to as a first command CMD_1st, and the command CMD input after the first command CMD_1st is referred to as a second command CMD_2nd.

The activation interval adjustment circuit 400 may extend an activation interval of the enable signal EN by blocking an activation of the deactivation control signal OFF when the first command CMD_1st is input and then the second command CMD_2nd is input until a certain timing corresponding to the plurality of activation interval setting signals MR<N:0>.

The activation interval adjustment circuit 400 may extend an activation interval of the enable signal EN by blocking an activation of the deactivation control signal OFF for a duration equal to a time difference between an input timing of the first command CMD_1st and an input timing of the second command CMD_2nd when the first command CMD_1st is input and then the second command CMD_2nd is input until a certain timing corresponding to the plurality of activation interval setting signals MR<0:N>.

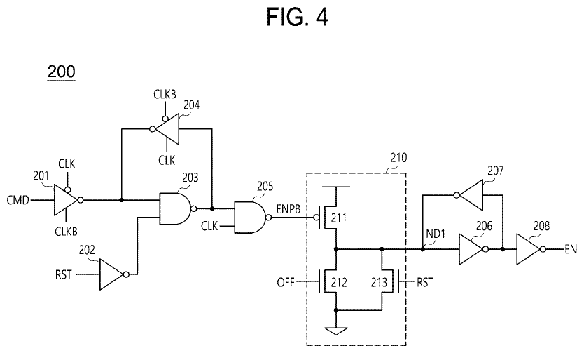

FIG. 4 is a diagram illustrating the signal generation circuit 200 of FIG. 3.

Referring to FIG. 4, the signal generation circuit 200 may include a plurality of logic gates 201 to 208 and a driver 210. The first logic gate 201 may invert the command CMD and may output an inverted command according to the clock signals CLK/CLKB. The first logic gate 201 may invert the command CMD and may output the inverted command when the clock signal CLK is at a low level. The second logic gate 202 may invert the reset signal RST and may output an inverted reset signal. The third logic gate 203 may output a result from performing a NAND operation on an output of the first logic gate 201 and an output of the second logic gate 202. The fourth logic gate 204 may invert an output of the third logic gate 203 according to the clock signals CLK/CLKB and may feed it back to an input of the third logic gate 203. The fourth logic gate 204 may invert the output of the third logic gate 203 and may feed it back to the input of the third logic gate 203 when the clock signal CLK is at a high level. The fifth logic gate 205 may perform a NAND operation on the output of the third logic gate 203 and the clock signal CLK and may output the activation control signal ENPB. The driver 210 may drive a first node ND1 to a high level in response to the activation control signal ENPB and may drive the first node ND1 to a low level in response to the deactivation control signal OFF. The driver 210 may drive the first node ND1 to a low level in response to the reset signal RST. The driver 210 may include first to third transistors 211 to 213. The first transistor 211 may have a source terminal coupled to a power terminal, a gate terminal receiving the activation control signal ENPB, and a drain terminal coupled to the first node ND1. The second transistor 212 may have a source terminal coupled to a ground terminal, a gate terminal receiving the deactivation control signal OFF, and a drain terminal coupled to the first node ND1. The third transistor 213 may have a source terminal coupled to the ground terminal, a gate terminal receiving the reset signal RST, and a drain terminal coupled to the first node ND1. The sixth logic gate 206 may output an inverted logic level of the first node ND1. The seventh logic gate 207 may invert an output of the sixth logic gate 206 and may feed it back to an input of the sixth logic gate 206. The eighth logic gate 208 may invert the output of the sixth logic gate 206 and may output the enable signal EN. For example, when the enable signal generation circuit 100 is configured for a write operation of a semiconductor apparatus, the enable signal generation circuit 100 may receive a write command as the command CMD and may use the enable signal EN as a write enable signal to define a write operation interval. In another example, when the enable signal generation circuit 100 is configured for a read operation of a semiconductor apparatus, the enable signal generation circuit 100 may receive a read command as the command CMD and may use the enable signal EN as a read enable signal to define a read operation interval. The write enable signal and the read enable signal described above are by way of example only, and embodiments of the present disclosure may be configured to generate each of the enable signals to define various operation intervals of a semiconductor apparatus.

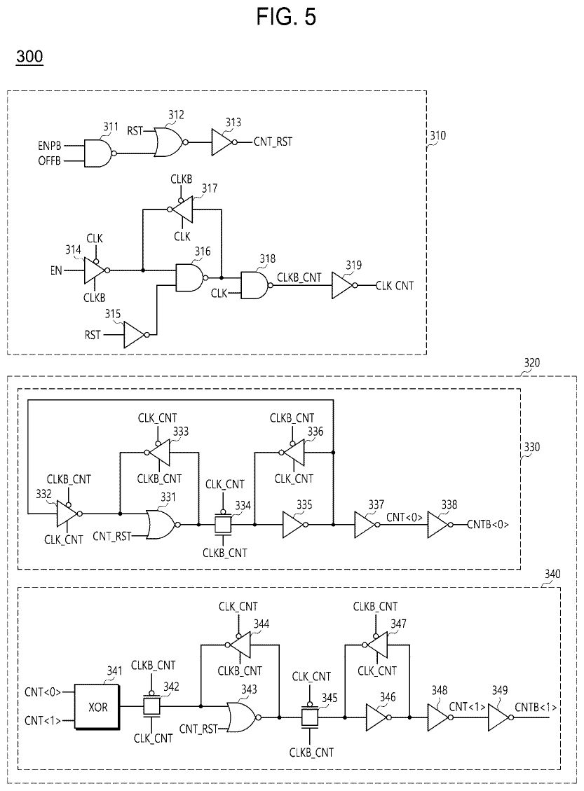

FIG. 5 is a diagram illustrating the counting circuit 300 of FIG. 3. The counting circuit 300 of FIG. 5 is illustrated in an example configured to generate the plurality of count result signals CNT<M:0>, CNTB<M:0> where M=1, i.e., a plurality of count result signals CNT<1:0>, CNTB<1:0>.

Referring to FIG. 5, the counting circuit 300 may include a counting control circuit 310 and a counting block 320.

The counting control circuit 310 may generate the count reset signal CNT_RST according to the activation control signal ENPB and the inverted deactivation control signal OFFB and may generate the count clock signals CLK_CNT/CLKB_CNT according to the enable signal EN and the clock signals CLK/CLKB.

The counting block 320 may change a value of one of the plurality of count result signals CNT<1:0> according to the count clock signals CLK_CNT/CLKB_CNT, for example, a count result signal CNT<0>, and may change a value of the other of the plurality of count result signals CNT<1:0> according to the count clock signals CLK_CNT/CLKB_CNT and the plurality of count result signals CNT<1:0>, for example, a count result signal CNT<1>. The counting block 320 may initialize the values of the plurality of count result signals CNT<1:0> according to the count reset signal CNT_RST.

The counting block 320 may include a first unit counting circuit 330 and a second unit counting circuit 340. The first unit counting circuit 330 may initialize the count result signal CNT<0> according to the count reset signal CNT_RST and may change a value of the count result signal CNT<0> according to the count clock signals CLK_CNT/CLKB_CNT. The second unit counting circuit 340 may initialize the count result signal CNT<1> according to the count reset signal CNT_RST and may change a value of the count result signal CNT<1> according to the values of the plurality of count result signals CNT<1:0> and the count clock signals CLK_CNT/CLKB_CNT.

The counting control circuit 310 may include a plurality of logic gates 311 to 319. The first logic gate 311 may output a result from performing a NAND operation on the activation control signal ENPB and the inverted deactivation control signal OFFB. The combination of the second logic gate 312 and the third logic gate 313 may perform an OR operation on the reset signal RST and an output of the first logic gate 311 and may output the count reset signal CNT_RST. The fourth logic gate 314 may invert the enable signal EN when the clock signal CLK is at a low level and output its result. The fifth logic gate 315 may invert the reset signal RST and may output an inverted reset signal. The sixth logic gate 316 may output a result from performing a NAND operation on an output of the fourth logic gate 314 and an output of the fifth logic gate 315. The seventh logic gate 317 may feedback an output of the sixth logic gate 316 as an input to the sixth logic gate 316 when the clock signal CLK is at a high level. The eighth logic gate 318 may perform a NAND operation on an output of the sixth logic gate 316 and the clock signal CLK and may output the count clock signal CLKB_CNT. The ninth logic gate 319 may invert the count clock signal CLKB_CNT and may output the count clock signal CLK_CNT.

The first unit counting circuit 330 may include a plurality of logic gates 331 to 338. The first logic gate 331 may output a result from performing a NOR operation on a signal input through a first input terminal and the count reset signal CNT_RST input through a second input terminal. The second logic gate 332 may invert an input signal and may output its result when the count clock signal CLK_CNT is at a high level. The third logic gate 333 may invert an output of the first logic gate 331 and feed its result back to the first input terminal of the first logic gate 331 when the count clock signal CLK_CNT is at a low level. The fourth logic gate 334 may bypass the output of the first logic gate 331 when the count clock signal CLK_CNT is at a low level. The fifth logic gate 335 may invert an output of the fourth logic gate 334 and may output its result. The sixth logic gate 336 may feed an output of the fifth logic gate 335 back to an input of the fifth logic gate 335 when the count clock signal CLK_CNT is at a high level. The seventh logic gate 337 may invert the output of the fifth logic gate 335 and may output the count result signal CNT<0>. The eighth logic gate 338 may invert the count result signal CNT<0> and may output the count result signal CNTB<0>.

The second unit counting circuit 340 may include a plurality of logic gates 341 to 349. The first logic gate 341 may output a result from performing an XOR operation on the count result signal CNT<0> and the count result signal CNT<1>. The second logic gate 342 may bypass an output of the first logic gate 341 when the count clock signal CLK_CNT is at a high level. The third logic gate 343 may output a result from performing a NOR operation on the count reset signal CNT_RST and an output of the second logic gate 342. The fourth logic gate 344 may feedback an output of the third logic gate 343 to an input of the third logic gate 343 when the count clock signal CLK_CNT is at a low level. The fifth logic gate 345 may bypass the output of the third logic gate 343 when the count clock signal CLK_CNT is at a low level. The sixth logic gate 346 may invert an output of the fifth logic gate 345 and may output its result. The seventh logic gate 347 may feed an output of the sixth logic gate 346 back to an input of the sixth logic gate 346 when the count clock signal CLK_CNT is at a high level. The eighth logic gate 348 may invert the output of the sixth logic gate 346 and may output the count result signal CNT<1>. The ninth logic gate 349 may invert the count result signal CNT<1> and may output the count result signal CNTB<1>.

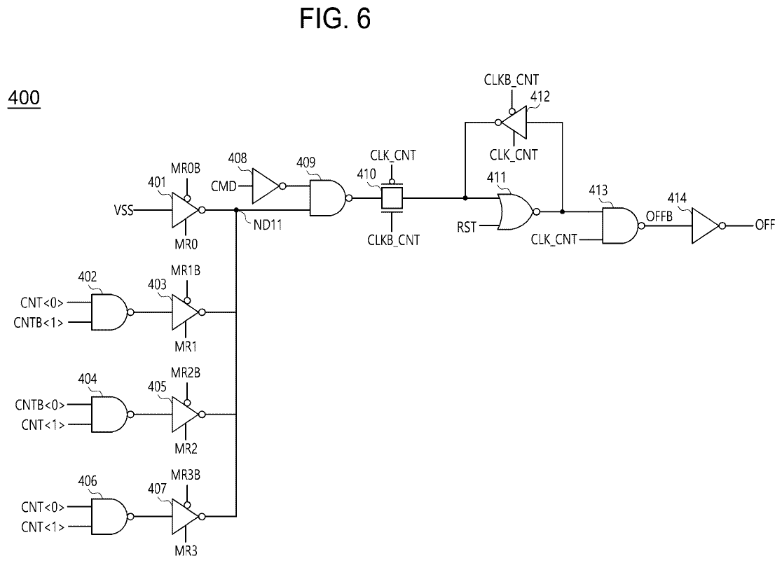

FIG. 6 is a diagram illustrating the activation interval adjustment circuit 400 of FIG. 3. The activation interval adjustment circuit 400 of FIG. 6 is an example configured to receive a plurality of activation interval setting signals MR<N:0> where N=3, i.e., a plurality of activation interval setting signals MR<3:0>.

Referring to FIG. 6, the activation interval adjustment circuit 400 may include a plurality of logic gates 401 to 414. The plurality of activation interval setting signals MRB<3:0> may be generated by inverting each of the same sequence of signals of the corresponding plurality of activation interval setting signals MR<3:0>. The first logic gate 401 may invert a logic level of a ground voltage VSS and may output its result to a first node ND11 when the activation interval setting signal MR0 is at a high level. The second logic gate 402 may output a result from performing a NAND operation on the count result signal CNT<0> and the count result signal CNTB<1>. The third logic gate 403 may invert an output of the second logic gate 402 and may output its result to the first node ND11 when the activation interval setting signal MR1 is at a high level. The fourth logic gate 404 may output a result from performing a NAND operation on the count result signal CNTB<0> and the count result signal CNT<1>. The fifth logic gate 405 may invert an output of the fourth logic gate 404 and may output its result to the first node ND11 when the activation interval setting signal MR2 is at a high level. The sixth logic gate 406 may output a result from performing a NAND operation on the count result signal CNT<0> and the count result signal CNT<1>. The seventh logic gate 407 may invert an output of the sixth logic gate 406 and may output its result to the first node ND11 when the activation interval setting signal MR3 is at a high level. The eighth logic gate 408 may invert a logic level of the command CMD and output its result. The ninth logic gate 409 may output a result from performing a NAND operation on an output of the eighth logic gate 408 and a logic level of the first node ND11. The tenth logic gate 410 may bypass an output of the ninth logic gate 409 when the count clock signal CLK_CNT is at a low level. The eleventh logic gate 411 may output a result from performing a NOR operation on the reset signal RST and an output of the tenth logic gate 410. The twelfth logic gate 412 may feedback an output of the eleventh logic gate 411 to an input of the eleventh logic gate 411 when the count clock signal CLK_CNT is at a high level. The thirteenth logic gate 413 may perform a NAND operation on the count clock signal CLK_CNT and the output of the eleventh logic gate 411 and may output the inverted deactivation control signal OFFB. The fourteenth logic gate 414 may invert the inverted deactivation control signal OFFB and may output the deactivation control signal OFF.

The activation interval adjustment circuit 400 may initialize the deactivation control signal OFF to a low level as the reset signal RST is input at a high level. The activation interval adjustment circuit 400 may hold the deactivation control signal OFF at a low level when the command CMD is input at a high level and then may activate the deactivation control signal OFF to a high level in response to the plurality of activation interval setting signals MR<3:0> and MRB<3:0>. For example, when the activation interval setting signal MR0 is at a high level, the activation interval adjustment circuit 400 may activate the deactivation control signal OFF to a high level in response to a rising edge of the count clock signal CLK_CNT generated after the command CMD is input at a high level regardless of the plurality of count result signals CNT<1:0>. When the activation interval setting signal MR1 is at a high level, the activation interval adjustment circuit 400 may activate the deactivation control signal OFF to a high level in conjunction with a rising edge of the count clock signal CLK_CNT generated after the plurality of count result signals CNT<1:0> transition to ‘01’. When the activation interval setting signal MR2 is at a high level, the activation interval adjustment circuit 400 may activate the deactivation control signal OFF to a high level in conjunction with a rising edge of the count clock signal CLK_CNT generated after the plurality of count result signals CNT<1:0> transition to ‘10’. When the activation interval setting signal MR3 is at a high level, the activation interval adjustment circuit 400 may activate the deactivation control signal OFF to a high level in conjunction with a rising edge of the count clock signal CLK_CNT generated after the plurality of count result signals CNT<1:0> transition to ‘11’.

The activation interval adjustment circuit 400 may block an activation of the deactivation control signal OFF for a duration equal to a time difference between an input timing of the first command CMD_1st and an input timing of the second command CMD_2nd, when the first command CMD_1st is input and then the second command CMD_2nd is input, until the first node ND11 transitions to a high level based on the plurality of activation interval setting signals MR<3:0> and the plurality of count result signals CNT<1:0>, CNTB<1:0>. Thus, an activation interval of the enable signal EN may be extended by the difference between an input timing of the first command CMD_1st and an input timing of the second command CMD_2nd from the timing when the first node ND11 transitions to a high level.

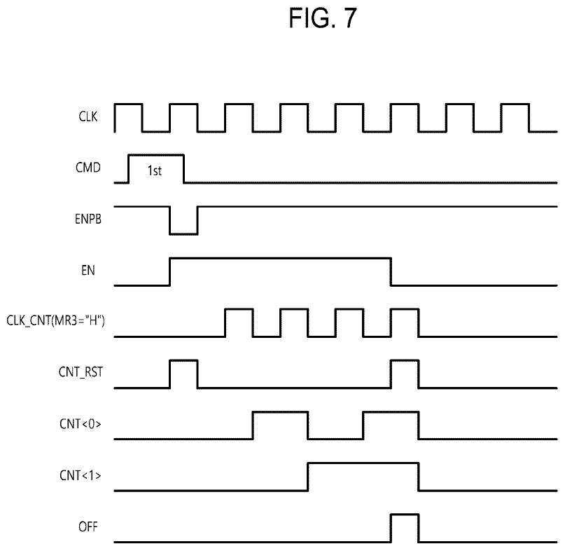

FIG. 7 is a timing diagram according to an example of an operation of the enable signal generation circuit 100 according to an embodiment of the present disclosure. Referring to FIGS. 3 to 7, an example of operation of the enable signal generation circuit 100 according to an embodiment of the present disclosure will be described. Among the plurality of activation interval setting signals MR<3:0>, it is assumed that the activation interval setting signal MR3 is set to a high level.

As the first command CMD_1st is input, the activation control signal ENPB may be generated, and the enable signal EN may be activated to a high level according to the activation control signal ENPB.

The count reset signal CNT_RST may be generated in response to the activation control signal ENPB. In response to the count reset signal CNT_RST, the plurality of count result signals CNT<1:0> may be initialized to ‘00’. FIG. 7 is an example in which the plurality of count result signals CNT<1:0> are already initialized according to the reset signal RST generated before the first command CMD_1st is input.

As the enable signal EN is activated to a high level, the count clock signal CLK_CNT is generated, and a value of the plurality of count result signals CNT<1:0> may be sequentially increased to from ‘00’ to ‘01’ to ‘10’ to ‘11’ according to the count clock signal CLK_CNT.

Because the activation interval setting signal MR3 is at a high level, the deactivation control signal OFF may be activated to a high level in conjunction with a rising edge of the count clock signal CLK_CNT generated after the plurality of count result signals CNT<1:0> transition to ‘11’. As the deactivation control signal OFF transitions to a high level, the inverted deactivation control signal OFFB transitions to a low level.

The enable signal EN may be deactivated to a low level in response to the deactivation control signal OFF at a high level. During an activation interval of the enable signal EN, i.e., a high level interval, an operation according to the first command CMD_1st may be performed. For example, if the first command CMD_1st is a write command, a write operation may be performed during the high level interval of the enable signal EN, and if the first command CMD_1st is a read command, a read operation may be performed during the high level interval of the enable signal EN.

The count reset signal CNT_RST may be generated according to the inverted deactivation control signal OFFB at a low level, and a value of the plurality of count result signals CNT<1:0> may be initialized to ‘00’ according to the count reset signal CNT_RST.

The enable signal generation circuit 100 may generate the enable signal EN having an activation interval corresponding to a four-cycle time (4 tCK) of the clock signal CLK when one command CMD, i.e., the first command CMD_1st, is input while the activation interval setting signal MR3 is set to a high level.

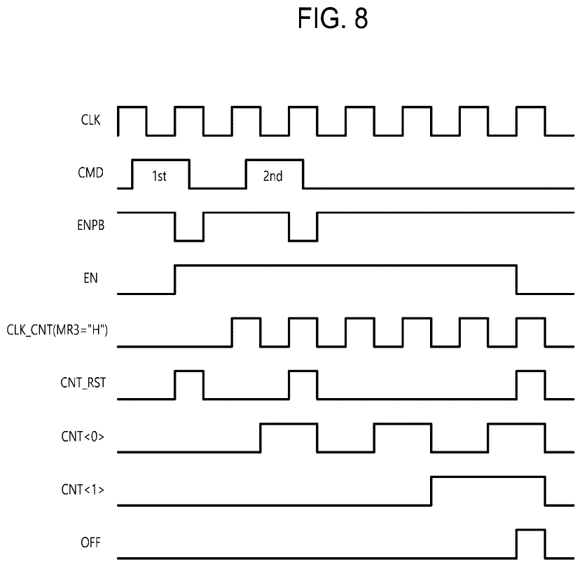

FIG. 8 is a timing diagram according to another example of an operation of the enable signal generation circuit 100 according to an embodiment of the present disclosure. FIG. 8 illustrates an example of operation of the enable signal generation circuit 100 according to a case in which the command CMD is continuously input at two-cycle time (2 tCK) interval of the clock signal CLK. Referring to FIGS. 3 to 8, an example of operation of the enable signal generation circuit 100 according to an embodiment of the present disclosure will be described. Among the plurality of activation interval setting signals MR<3:0>, it is assumed that the activation interval setting signal MR3 is set to a high level.

As the first command CMD_1st is input, the activation control signal ENPB may be generated, and the enable signal EN may be activated to a high level according to the activation control signal ENPB.

The count reset signal CNT_RST may be generated in response to the activation control signal ENPB. In response to the count reset signal CNT_RST, the plurality of count result signals CNT<1:0> may be initialized to ‘00’. FIG. 8 shows an example in which the plurality of count result signals CNT<1:0> are already initialized according to the reset signal RST generated before the first command CMD_1st is input.

As the enable signal EN is activated to a high level, the count clock signal CLK_CNT is generated, and a value of the plurality of count result signals CNT<1:0> may be increased to ‘01’ according to the count clock signal CLK_CNT.

After the first command CMD_1st is input, the second command CMD_2nd may be input after a two-cycle time (2 tCK) of the clock signal CLK, and the activation control signal ENPB may be generated again as the second command CMD_2nd is input.

The count reset signal CNT_RST may be generated according to the activation control signal ENPB. Based on the count reset signal CNT_RST, the plurality of count result signals CNT<1:0> may be initialized to ‘00’ instead of increasing from ‘01’ to ‘10’.

According to the count clock signal CLK_CNT, a value of the plurality of count result signals CNT<1:0> may be sequentially increased from ‘00’ to ‘01’ to ‘10’ to ‘11’.

Because the activation interval setting signal MR3 is at a high level, the deactivation control signal OFF may be activated to a high level in conjunction with a rising edge of the count clock signal CLK_CNT generated after the plurality of count result signals CNT<1:0> transition to ‘11’. As the deactivation control signal OFF transitions to a high level, the inverted deactivation control signal OFFB transitions to a low level.

The enable signal EN may be deactivated to a low level in response to the deactivation control signal OFF at a high level.

According to the inverted deactivation control signal OFFB at a low level, the count reset signal CNT_RST may be generated, and according to the count reset signal CNT_RST, a value of the plurality of count result signals CNT<1:0> may be initialized to ‘00’.

As described with reference to FIG. 7, the enable signal generation circuit 100 may generate the enable signal EN having an activation interval corresponding to a four-cycle time (4 tCK) of the clock signal CLK in response to one command CMD when the activation interval setting signal MR3 is set to a high level.

As shown in FIG. 8, the enable signal generation circuit 100 may extend an activation interval of the enable signal EN when the first command CMD_1st and the second command CMD_2nd are input consecutively at an interval of two-cycle time (2 tCK) of the clock signal CLK while the activation interval setting signal MR3 is set to a high level. The enable signal generation circuit 100 may activate the enable signal EN in response to the first command CMD_1st and then may extend an activation interval of the enable signal EN by four-cycle time (4 tCK) of the clock signal CLK in response to the second command CMD_2nd. As a result, when the first command CMD_1st and the second command CMD_2nd are input consecutively at an interval of two-cycle time (2 tCK) of the clock signal CLK while the activation interval setting signal MR3 is set to a high level, the enable signal EN having an activation interval corresponding to six-cycle time (6 tCK) of the clock signal CLK can be generated.

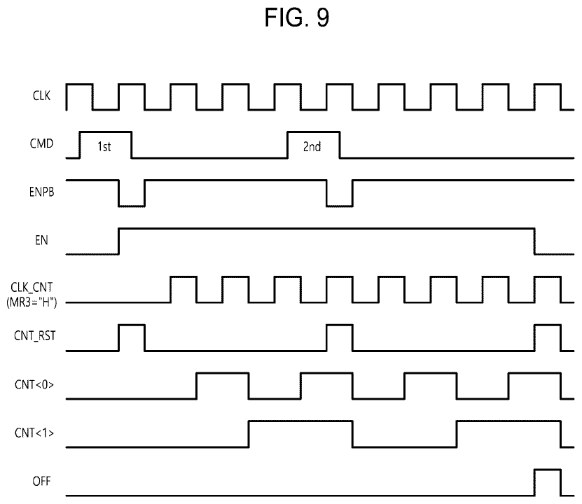

FIG. 9 is a timing diagram according to another example of an operation of the enable signal generation circuit 100 according to an embodiment of the present disclosure. FIG. 9 illustrates an example of an operation of the enable signal generation circuit 100 according to a case in which the command CMD is continuously input at four-cycle time (4 tCK) interval of the clock signal CLK. Referring to FIGS. 3 to 9, an example of operation of the enable signal generation circuit 100 according to an embodiment of the present disclosure will be described. Among the plurality of activation interval setting signals MR<3:0>, it is assumed that the activation interval setting signal MR3 is set to a high level.

As the first command CMD_1st is input, the activation control signal ENPB may be generated, and the enable signal EN may be activated to a high level according to the activation control signal ENPB.

The count reset signal CNT_RST may be generated in response to the activation control signal ENPB. In response to the count reset signal CNT_RST, the plurality of count result signals CNT<1:0> may be initialized to ‘00’. FIG. 9 illustrates an example in which the plurality of count result signals CNT<1:0> are already initialized according to the reset signal RST generated before the first command CMD_1st is input.

As the enable signal EN is activated to a high level, the count clock signal CLK_CNT is generated, and a value of the plurality of count result signals CNT<1:0> may be sequentially increased from ‘00’ to ‘01’ to ‘10’ to ‘11’ according to the count clock signal CLK_CNT.

Before a value of the plurality of count result signals CNT<1:0> is increased to ‘11’, the second command CMD_2nd may be input at a four-cycle time (4 tCK) of the clock signal CLK after the first command CMD_1st is input.

If the second command CMD_2nd is not input, the deactivation control signal OFF may be activated to a high level as a value of the plurality of count result signals CNT<1:0> transitions to ‘11’, but an activation may be blocked by keeping the deactivation control signal OFF at a low level in response to an input of the second command CMD_2nd.

As the second command CMD_2nd is input, the activation control signal ENPB may be generated again.

The count reset signal CNT_RST may be generated in response to the activation control signal ENPB. Based on the count reset signal CNT_RST, the plurality of count result signals CNT<1:0> may be initialized to ‘00’.

According to the count clock signal CLK_CNT, a value of the plurality of count result signals CNT<1:0> may be sequentially increased from ‘00’ to ‘01’ to ‘10’ to ‘11’.

Because there is no other command input at the timing in which a value of the plurality of count result signals CNT<1:0> transitions to ‘11’ and the activation interval setting signal MR3 is at a high level, the deactivation control signal OFF may be activated to a high level in conjunction with a rising edge of the count clock signal CLK_CNT generated after the plurality of count result signals CNT<1:0> transition to ‘11’. As the deactivation control signal OFF transitions to a high level, the inverted deactivation control signal OFFB transitions to a low level.

The enable signal EN may be deactivated to a low level in response to the deactivation control signal OFF at a high level.

According to the inverted deactivation control signal OFFB at a low level, the count reset signal CNT_RST may be generated, and according to the count reset signal CNT_RST, a value of the plurality of count result signals CNT<1:0> may be initialized to ‘00’.

As shown in FIG. 9, the enable signal generation circuit 100 may extend an activation interval of the enable signal EN when the first command CMD_1st and the second command CMD_2nd are input consecutively at an interval of four-cycle time (4 tCK) of the clock signal CLK while the activation interval setting signal MR3 is set to a high level. The enable signal generation circuit 100 may activate the enable signal EN by four-cycle time (4 tCK) of the clock signal CLK in response to the first command CMD_1st and may extend an activation interval of the enable signal EN by four-cycle time (4 tCK) of the clock signal CLK in response to the second command CMD_2nd. As a result, when the first command CMD_1st and the second command CMD_2nd are input consecutively at interval of four-cycle time (4 tCK) of the clock signal CLK while the activation interval setting signal MR3 is set to a high level, the enable signal EN having an activation interval corresponding to eight-cycle time (8 tCK) of the clock signal CLK can be generated.

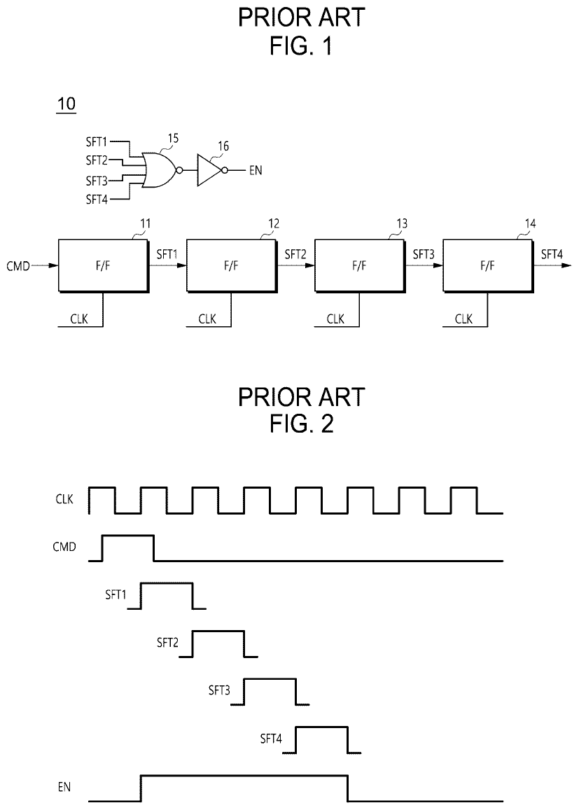

The enable signal generation circuit of the prior art described with reference to FIGS. 1 and 2 suffers from the problem that it must include flip-flops and asynchronous elements that increase in proportion to an activation interval of the enable signal, thereby increasing circuit area and asynchronous timing.

However, the present disclosure, as described above, does not use flip-flops and asynchronous elements, and can adjust the activation interval of the enable signal EN by simply setting the plurality of activation interval setting signals MR<3:0>, MRB<3:0>, and can automatically extend the activation interval of the enable signal without any control when successive commands are input, thereby reducing circuit area and preventing asynchronous timing from occurring.

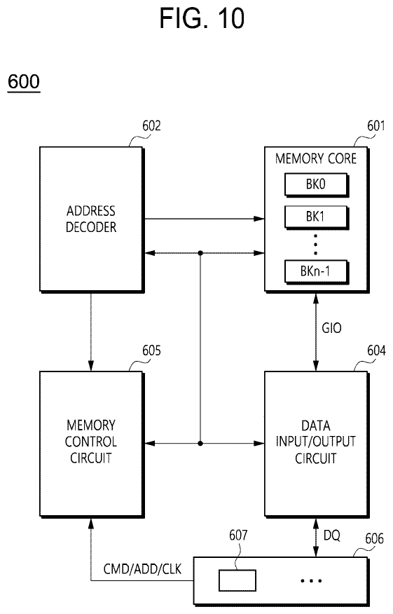

FIG. 10 is a diagram illustrating a semiconductor apparatus 600 according to an embodiment of the present disclosure.

Referring to FIG. 10, the semiconductor apparatus 600 may include a memory core 601, an address decoder 602, a data input/output circuit 604, a memory control circuit 605, and an input/output pad circuit 606.

The data input/output circuit 604 or the memory control circuit 605 may include a plurality of enable signal generation circuits 100 according to an embodiment of the present disclosure.

The memory core 601 may include a plurality of memory cells, and the plurality of memory cells may include at least one of a volatile memory and a non-volatile memory. The volatile memory may include static RAM (SRAM), dynamic RAM (DRAM), and synchronous DRAM (SDRAM), and the non-volatile memory may include read only memory (ROM), programmable ROM (PROM), EEPROM (Electrically Erase and Programmable ROM), EPROM (Electrically Programmable ROM), flash memory, PRAM (Phase change RAM), MRAM (Magnetic RAM), RRAM (Resistive RAM), and FRAM (Ferroelectric RAM). The unit cells of the memory core 601 may be divided into a plurality of memory regions, such as a plurality of memory banks BK0 to BKn-1 (hereinafter referred to as banks).

The address decoder 602 may be coupled to the memory control circuit 605 and the memory core 601. The address decoder 602 may decode an address signal provided by the memory control circuit 605 and may access the memory core 601 in response to the decoding result.

The data input/output circuit 604 may be coupled to memory core 601 through a global input/output line GIO. The data input/output circuit 604 may exchange data with an external system or the memory core 601.

The memory control circuit 605 may be coupled to the memory core 601, the address decoder 602, and the data input/output circuit 604. The memory control circuit 605 may be provided with a command CMD, an address ADD, a clock signal CLK, and the like. The memory control circuit 605 may provide an address decoded through the address decoder 602 to the data input/output circuit 604. The memory control circuit 605 may control a test operation and a normal operation of the semiconductor apparatus 600. The normal operation may include a read operation, a write operation, and an address processing operation.

A test mode or the command CMD, for example, a mode register write command may be used to set the plurality of activation interval setting signals MR<N:0> corresponding to each of the plurality of enable signal generation circuits 100 to different values, ‘N’ being defined as a non-negative integer. The memory control circuit 605 may store the plurality of activation interval setting signals MR<N:0> in an internal circuit, for example, in a region corresponding to each of the plurality of enable signal generation circuits 100, among the storage regions of a mode register, and may provide the plurality of activation interval setting signals MR<N:0> stored in each region to each of the plurality of enable signal generation circuits 100. Thus, the plurality of enable signal generation circuits 100 may generate enable signals EN having different activation intervals according to the activation interval setting signals MR<N:0> set to different values.

The input/output pad circuit 606 may include a plurality of pads 607 for receiving the command CMD, the address ADD, and the clock signal CLK, and for inputting and outputting data DQ.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. An enable signal generation circuit, comprising:
a signal generation circuit configured to synchronize a command to a clock signal to activate an enable signal and configured to deactivate the enable signal in response to a deactivation control signal;
a counting circuit configured to count the clock signal to generate a plurality of count result signals when the enable signal is activated; and
an activation interval adjustment circuit configured to generate the deactivation control signal at a first timing based on transition timings of the plurality of count result signals when the command is input.

2. The enable signal generation circuit of claim 1, wherein the counting circuit is configured to generate a count clock signal in accordance with the enable signal and the clock signal and configured to generate the plurality of count result signals in accordance with the count clock signal.

3. The enable signal generation circuit of claim 1, wherein the signal generation circuit is configured to synchronize the command to the clock signal to generate an activation control signal and configured to activate the enable signal in accordance with the activation control signal.

4. The enable signal generation circuit of claim 3, wherein the counting circuit comprises:
a counting control circuit configured to generate a count reset signal according to the activation control signal and an inverted deactivation control signal, the inverted deactivation control signal having a logic level opposite to the deactivation control signal, and configured to generate a count clock signal according to the enable signal and the clock signal; and
a counting block configured to change a value of any one of the plurality of count result signals in accordance with the count clock signal, configured to change a value of another count result signal, among the plurality of count result signals, in accordance with a value of the plurality of count result signals and the count clock signal, and configured to reset a value of the plurality of count result signals in accordance with the count reset signal.

5. The enable signal generation circuit of claim 1, wherein the activation interval adjustment circuit is configured to adjust the first timing according to a plurality of activation interval setting signals.

6. The enable signal generation circuit of claim 1, wherein the activation interval adjustment circuit is configured to extend an activation interval of the enable signal by blocking an activation of the deactivation control signal when the first command is input and then the second command is input until the first timing.

7. The enable signal generation circuit of claim 1, wherein the activation interval adjustment circuit is configured to extend an activation interval of the enable signal by blocking an activation of the deactivation control signal for a duration equal to a time difference between an input timing of the first command and an input timing of a second command when the first command is input and then the second command is input until the first timing.

8. A semiconductor apparatus, comprising:
a memory core including a plurality of memory cells;
a data input/output circuit configured to be coupled to the memory core and configured to exchange data with an external system or the memory core;
a plurality of enable signal generation circuits configured to count a clock signal to generate a plurality of count result signals, configured to generate a deactivation control signal at a first timing determined according to a plurality of activation interval setting signals and transition timings of the plurality of count result signals, configured to synchronize a command to the clock signal to activate an enable signal, and configured to deactivate the enable signal according to the deactivation control signal; and
a memory control circuit configured to be coupled to the memory core and the data input/output circuit, and configured to provide the plurality of activation interval setting signals, the command provided from an external source, and the clock signal to the plurality of enable signal generation circuits.

9. The semiconductor apparatus of claim 8, wherein memory control circuit is configured to store the plurality of activation interval setting signals set by a test mode or a mode register write command in an internal circuit and configured to provide the plurality of activation interval setting signals to the plurality of enable signal generation circuits.

10. The semiconductor apparatus of claim 8, wherein memory control circuit is configured to provide the plurality of activation interval setting signals with different values set by a test mode or a mode register write command to the plurality of enable signal generation circuits.

11. The semiconductor apparatus of claim 8, wherein any one of the plurality of enable signal generation circuits is configured to receive a write command as the command and configured to generate a write enable signal defining a write operation interval as the enable signal.

12. The semiconductor apparatus of claim 11, wherein another enable signal generation circuit, among the plurality of enable signal generation circuits, is configured to receive a read command as the command, and configured to generate a read enable signal defining a read operation interval as the enable signal.

13. The semiconductor apparatus of claim 8, wherein each of the plurality of enable signal generation circuits comprises:
a signal generation circuit configured to synchronize the command to the clock signal to activate the enable signal and configured to deactivate the enable signal in response to the deactivation control signal;
a counting circuit configured to count the clock signal to generate the plurality of count result signals when the enable signal is activated; and
an activation interval adjustment circuit configured to generate the deactivation control signal at the first timing when the command is input.

14. The semiconductor apparatus of claim 13, wherein the counting circuit is configured to generate a count clock signal in accordance with the enable signal and the clock signal and configured to generate the plurality of count result signals in accordance with the count clock signal.

15. The semiconductor apparatus of claim 13, wherein the signal generation circuit is configured to synchronize the command to the clock signal to generate an activation control signal and configured to activate the enable signal in accordance with the activation control signal.

16. The semiconductor apparatus of claim 15, wherein the counting circuit comprises:
a counting control circuit configured to generate a count reset signal according to the activation control signal and an inverted deactivation control signal, the inverted deactivation control signal having a logic level opposite to the deactivation control signal, and configured to generate a count clock signal according to the enable signal and the clock signal; and
a counting block configured to change a value of any one of the plurality of count result signals in accordance with the count clock signal, configured to change a value of another count result signal, among the plurality of count result signals, in accordance with a value of the plurality of count result signals and the count clock signal, and configured to reset a value of the plurality of count result signals in accordance with the count reset signal.

17. The semiconductor apparatus of claim 13, wherein the activation interval adjustment circuit is configured to extend an activation interval of the enable signal by blocking an activation of the deactivation control signal when the first command is input and then the second command is input until the first timing.

18. The semiconductor apparatus of claim 13, wherein the activation interval adjustment circuit is configured to extend an activation interval of the enable signal by blocking an activation of the deactivation control signal for a duration equal to a time difference between an input timing of the first command and an input timing of the second command when the first command is input and then the second command is input until the first timing.

19. An enable signal generation circuit, comprising:
a signal generation circuit configured to synchronize a command to a clock signal to activate an enable signal and configured to deactivate the enable signal in response to an activation of a deactivation control signal; and
an activation interval adjustment circuit configured to extend an activation interval of the enable signal by blocking an activation of the deactivation control signal when a first command of the command is input and then a second command of the command is input until a first timing.

20. The enable signal generation circuit of claim 19, further comprising a counting circuit configured to generate a count clock signal based on the enable signal and the clock signal and configured to generate a plurality of count result signals as a reference for the first timing based on the count clock signal.

21. The enable signal generation circuit of claim 20, wherein the counting circuit comprises:
a counting control circuit configured to generate a count reset signal according to the activation control signal and an inverted deactivation control signal, the inverted deactivation control signal having a logic level opposite to the deactivation control signal, and configured to generate a count clock signal according to the enable signal and the clock signal; and
a counting block configured to change a value of any one of the plurality of count result signals in accordance with the count clock signal, configured to change a value of another count result signal, among the plurality of count result signals, in accordance with a value of the plurality of count result signals and the count clock signal, and configured to reset a value of the plurality of count result signals in accordance with the count reset signal.

22. The enable signal generation circuit of claim 19, wherein the signal generation circuit is configured to synchronize the command to the clock signal to generate an activation control signal and configured to activate the enable signal in accordance with the activation control signal.

23. The enable signal generation circuit of claim 20, wherein the activation interval adjustment circuit is configured to select one transition timing, among transition timings of the plurality of count result signals, according to a plurality of activation interval setting signals as the first timing.

24. The enable signal generation circuit of claim 19, wherein the activation interval adjustment circuit is configured to extend an activation interval of the enable signal by blocking an activation of the deactivation control signal for a duration equal to a time difference between an input timing of the first command and an input timing of the second command when the first command is input and then the second command is input until the first timing.
